(19) United States
(12) Patent Application Publication
(10) Pub. No.: US 2014/0127951 A1
(43) Pub. Date: May 8, 2014

(54) CONNECTING DEVICE FOR SOLAR PANEL

(71) Applicants: Hanns Watrinet, Eschenbach (CH); Roger Loser, Uster (CH); Thomas Burger, Steg (CH)

(72) Inventors: Hanns Watrinet, Eschenbach (CH); Roger Loser, Uster (CH); Thomas Burger, Steg (CH)

(73) Assignee: HUBER+SUHNER AG, Herisau (CH)

(21) Appl. No.: 14/123,712

(22) PCT Filed: Apr. 24, 2012
(86) PCT No.: PCT/EP2012/057472

§ 371 Date: Dec. 3, 2013

(30) Foreign Application Priority Data
Jun. 3, 2011 (CH) 0094211

(51) Int. Cl. H01R 13/66; H01L 31/048

(52) U.S. Cl. CPC H01R 13/665; H01L 31/0485
USPC 439/709; 439/885

(57) ABSTRACT

The invention relates to a connecting device (1) for a solar panel (14, 18). The connecting device (1) comprises contacts (4.1-4.4) for operatively connecting differently arranged connecting strips (15, 19) of more than one type of solar panel (14, 18).

The invention relates to a connection device, or a junction box, for a solar panel according to the preamble of the independent claim.

Connection strips for solar panels are effectively standardized. There are two different connection designs that have become established in the market. In a first embodiment, the connection strips—typically four—are arranged laterally next to each other in a row (4×1 configuration). In a second embodiment, the connection strips are arranged in two rows on two strips each (2×2 configuration) in the corners of a rectangle (2×2 configuration). The distance between the individual strips is usually 12 to 15 mm. The strips are usually contacted by way of clamping, soldering or resistance welding.

The following two industrial property rights were filed by the applicant and are directed to junction boxes: WO2008/000101 and WO2008/124951.

A wide range of publications with regard to junction boxes exists in the prior art. Some examples are listed below: for example, EP 2282349, which was filed in 2009 by Yamaichi Electronics GmbH, shows a junction box for solar panels having a 2×2 arrangement of the connection strips. Further junction boxes are known, for example, from WO10052210 (Tyco), U.S. Pat. No. 7,824,190 (Weidmuller Interface), WO10025223 (Heyco Inc.), US2010039781 (Alltop Electronics), WO09122456 (Compel Electronics), and DE102008003448 (Yamaichi Electronics Co. Ltd.).

The junction boxes known from the prior art have the drawback that a specially designed separate junction box is required for each connection design. This has an adverse effect in terms of production costs.

This object is achieved by the connection device defined in the independent claim.

A connection device according to the invention for a solar panel comprises contacts suited for operatively connecting differently arranged connection strips of more than one type of solar panels. In one embodiment, the contacts are laterally offset at a defined first distance relative to a first axis. The contacts are also arranged at a likewise defined second distance relative to the corner points of a rectangle. In one embodiment, two outer contacts are arranged on one side of the first axis and two inner contacts are arranged on the opposing side. The connection device is advantageously integrated into a junction box for a solar panel. The contacts are arranged in a connection shaft for this purpose, which is delimited by shaft walls on four sides. The shaft walls are generally formed by the housing of the junction box. Depending on the embodiment, the contacts may be arranged so as to be vertical and/or horizontal.

Depending on the embodiment, the contacts may all be designed to protrude from the same shaft wall. If needed, the contacts may also be formed on opposing shaft walls and/or shaft walls arranged at an angle with respect to each other. Corresponding arrangement examples are shown in the figures below. Other mixed forms are possible. The shaft walls may be designed to follow the contacts or the arrangement thereof. The contacts may be designed to be planar, or curved or bent at least in one direction.

The invention will be described in greater detail based on the exemplary embodiments shown in the following drawings and the related descriptions. In the drawings:

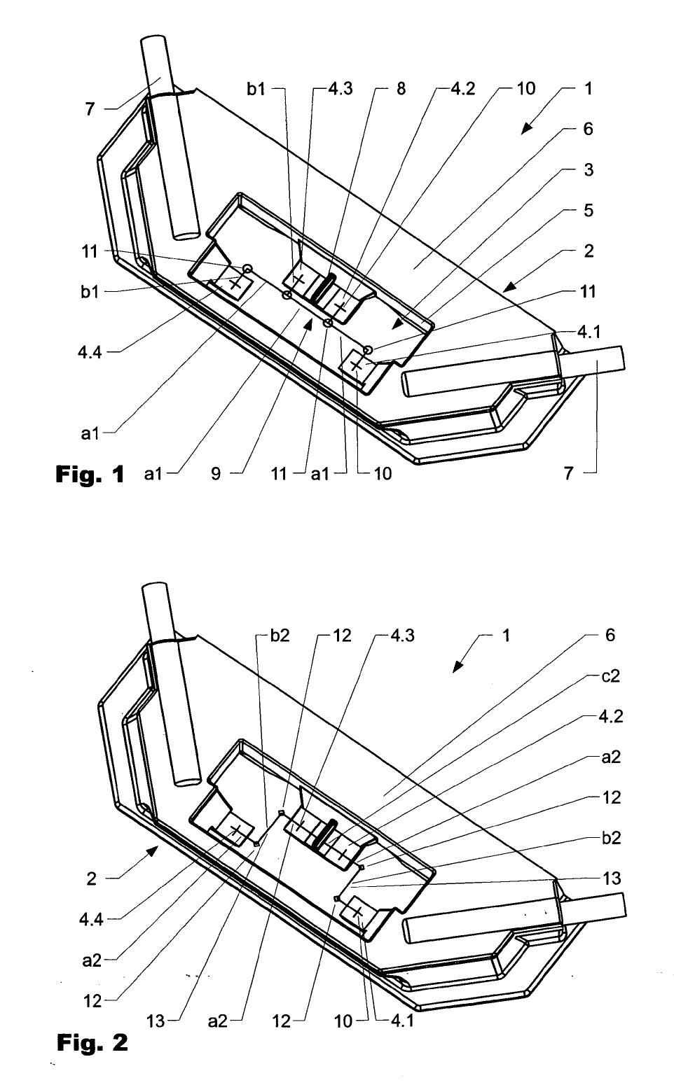

FIG. 1 shows a connection device according to the invention obliquely from the front and above;

FIG. 2 shows a connection device according to the invention obliquely from the front and above;

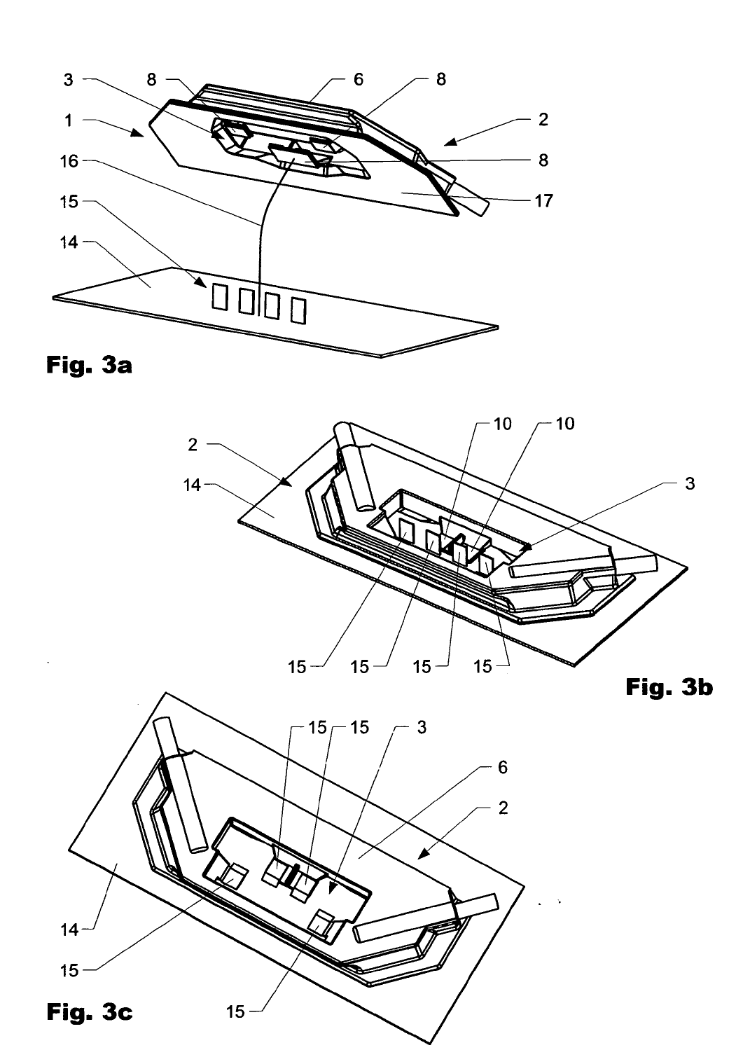

FIG. 3 shows the installation of a connection device on a first embodiment of a solar panel;

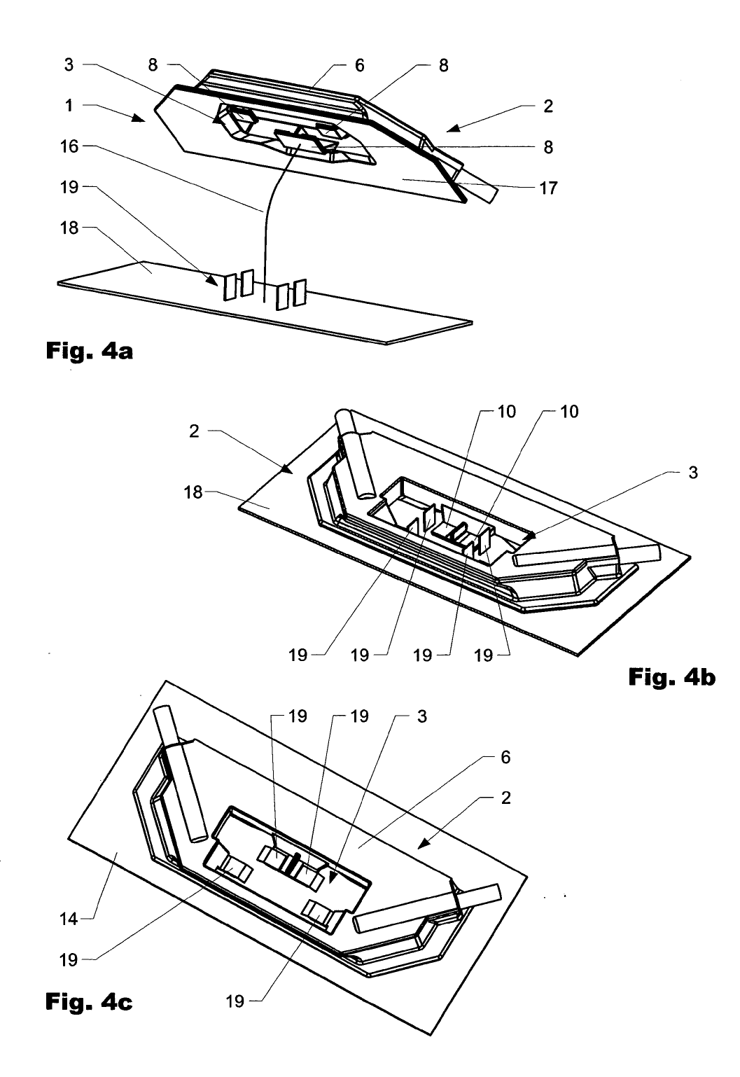

FIG. 4 shows the installation of a connection device on a second embodiment of a solar panel;

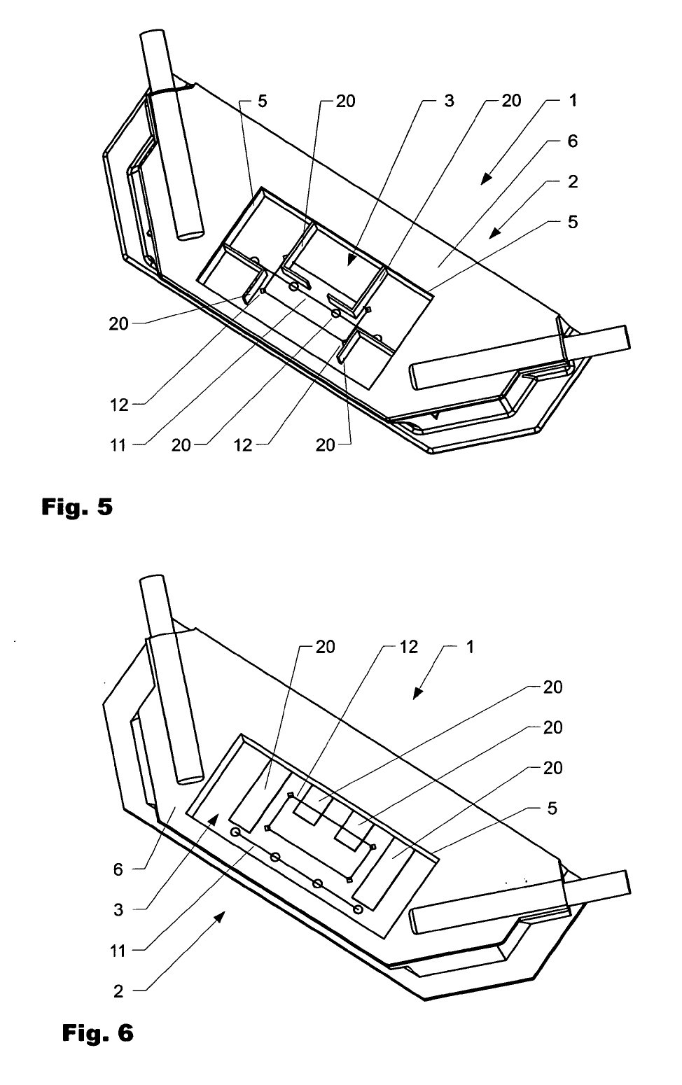

FIG. 5 shows a second embodiment of a connection device; and

FIG. 6 shows a third embodiment of a connection device.

The figures and related description use like reference numerals for corresponding parts.

FIGS. 1 and 2 each show a perspective illustration of a connection device 1 obliquely from the front and above. FIG. 3 shows the installation of the connection device on a first solar panel 10. FIG. 4 shows the installation of the connection device 1 on a second solar panel 15.

In the embodiment shown, the connection device 1 is integrated into a junction box 2, which is shown only schematically. The connection device 1 has a connection shaft 3, in which contacts 4 are arranged along shaft walls 5. The connection shaft 3 is formed by a housing 6 of the junction box 2. The shaft extends in the vertical direction (z-direction), is closed here on four sides and disposed close to the edge. After the junction box 2 has been operatively connected to a solar panel, the connection shaft 2 can be potted with a sealant. The contacts 4 are made of sheet metal and protrude horizontally into the shaft 3 close to the bottom (near the shaft end on the rear wall side). In the interior of the housing 6, the contacts are normally operatively connected to any electronics that may be present (not shown) and a connection cable 7.

As can be seen from FIGS. 3 and 4, the rear sides of the contacts 4 may be supported by a portion 8 of the housing 6. This prevents the contacts 4 from being accidentally deformed during connection to a solar panel (see FIGS. 3 and 4). Another aspect is that better insulation with respect to the solar panel is achieved by the distance during soldering.

A total of four contacts 4.1 to 4.4 can be seen in the shown embodiment. While two contacts 4.2, 4.3 are arranged laterally next to each other along a longer shaft side, the other two contacts 4.1, 4.4 are arranged diametrically opposed from each other on a respective narrow side of the shaft 3.

The arrangement of the contacts 4.1 to 4.4 satisfies two conditions:

(a) see FIG. 1: The centers 10 of the contacts 4.1 to 4.4 are equidistantly arranged laterally next to each other at a first distance a with respect to the longitudinal direction of a first axis 9, which here extends in the longitudinal shaft direction. In the transverse direction relative to the first axis 9, the contacts 4.1 to 4.4 are equidistantly arranged at a second distance b, with the outer two contacts 4.1 and 4.4 being arranged below, and the two inner contacts 4.2 and 4.3 being arranged above, the first axis 9. Linear positions of connection strips of a solar panel of the 4×1 type are arranged along the first axis 9, which is schematically indicated by circles 11 (see FIG. 3).

(b) see FIG. 2: With respect to a second, rectangular position of connection strips of a solar panel of the 2×2 type, which are schematically indicated by rhombi 12, the centers 10 of the contacts 4.1 to 4.4 are arranged in pairs in the longitudinal direction at a first distance a2 from two second axes 13 extending in the transverse direction. The centers 10 are arranged in pairs at a distance b2 from each other in the transverse direction. There is a distance c between the center two contacts 4.2 and 4.3.

FIGS. 3a to 3c show in schematic illustrations in three steps how the connection device 1 according to FIG. 1 is operatively connected to a first solar panel 14 of the 4×1 type. In this panel, connection strips 15 are arranged in a row laterally next to each other. In a first step (FIG. 3a), the connection device 1 is placed on the first solar panel 14. This is schematically indicated by a curve 16, which illustrates the relative movement. FIG. 3b shows the junction box 2 after being placed on the first solar panel 14. The rear wall 17 of the junction box 2 is seated on the first solar panel 14. The first connection strips 15 are arranged along the first axis 9 shown in FIG. 1 and are located in the first positions 11. The connection strips 14 are brought close to the contacts 4.1 to 4.4 by lateral bending, as shown in FIG. 3c, and are operatively connected thereto in a conducting manner.

FIGS. 4a to 4c show in schematic illustrations in three steps how the connection device 1 according to FIG. 2 is operatively connected to a second panel 18 of the 2×2 type. Here, the connection strips 19 are arranged in a rectangle. In a first step (FIG. 4a), the connection device 1 is placed on the second solar panel 18. This is schematically indicated by a curve 16, which illustrates the relative movement. FIG. 4b shows the junction box 2 after being placed on the second solar panel 18. The rear wall 17 of the junction box 2 is seated on the second solar panel 18. The second connection strips 19 are arranged in the second position 12 shown in FIG. 2. The connection strips 19 are brought close to the contacts 4.1 to 4.4 by lateral bending, as shown in FIG. 4c, and are operatively connected thereto in a conducting manner.

FIG. 5 shows a perspective illustration of a second embodiment of a connection device 1 obliquely from the front and above. The connection device 1 is again integrated into a junction box 2 for solar panels. The junction box 2 comprises a housing 6 having a shaft 3. Contacts 20 are arranged in the shaft 3, which in the shown embodiment have an L-shaped cross-section and protrude vertically from the shaft walls 5. The contacts 20 are arranged vertically in such a way they are suited for being operatively connected to connection strips (see FIGS. 3a and 4a) of the 4×1 type and 2×2 type, which are located in the first positions (4×1 type) 11 and the second positions (2×2 type) 12, respectively. Since the contacts 20 are arranged vertically, the connection strips of the solar panels are not bent in this embodiment, but are operatively connected to the contacts from the side. The operative connection is achieved by way of soldering or welding, for example.

FIG. 6 shows a perspective illustration of a third embodiment of a connection device 1 obliquely from the front and above. The connection device 1 is again integrated into a junction box 2 for solar panels. The junction box 2 comprises a housing 6 having a shaft 3. Rectangular contacts 20 can be seen in the shaft 3, which in the shown embodiment are arranged parallel to each other and are designed to have differing lengths and which protrude from the shaft wall 5. The contacts 20 are arranged horizontally in such a way they are suited for being operatively connected to connection strips (see FIGS. 3a and 4a) of different solar panels, for example of the 4×1 type and of the 2×2 type, which are located in the first positions (4×1 type) 11 and the second positions (2×2 type) 12, respectively. Since the contacts 20 are arranged vertically, the connection strips of the solar panels are not bent in this embodiment, but operatively connected to the contacts from the side. The operative connection is achieved by way of soldering or welding, for example. If needed, the two outer contacts may also be formed on the opposing shaft wall. Other mixed forms are possible.

### REFERENCE NUMERALS

a1 first distance
b1 second distance
a2 third distance
b2 fourth distance
c fifth distance
1 connection device
2 junction box
3 connection shaft (shaft)
4 contacts (4.1 to 4.4)
5 shaft walls
6 housing (junction box)
7 cable
8 portion (of the housing)
9 first axis
10 centers (contacts)
11 first position connection strips (4×1 type)
12 second position connection strips (2×2 type)
13 second axes
14 first solar panel (4×1 type)
15 first connection strips (4×1 type)
16 curve (installation)
17 rear wall (housing)
18 second solar panel (2×2 type)
19 second connection strips (2×2 type)
20 contacts

1. A connection device for a solar panel, the connection device comprising: contacts operatively connecting differently arranged connection strips of more than one type of solar panels.

2. The connection device according to claim 1, wherein the contacts are arranged at a first distance a1 relative to a first axis.

3. The connection device according to claim 2, wherein the contacts are arranged in pairs at a third distance a2 relative to two second axes.

4. The connection device according to claim 3, wherein the first distance a1 is approximately twice as large as the third distance a2.

5. The connection device according to claim 2, wherein two outer contacts are arranged on one side of the first axis and two inner contacts are arranged on the an opposing side.

6. The connection device according to claim 1, wherein the connection device is integrated into a junction box.

7. The connection device according to claim 1, wherein the contacts are arranged in a connection shaft.

8. The connection ,device according to claim 7, wherein the connection shaft is delimited by shaft walls on four sides.

9. The connection device according to claim 8, wherein the shaft walls are formed by the housing of the junction box.

10. The connection device according to claim 1, wherein the contacts are arranged so as to be horizontal and/or vertical.

11. The connection device according to claim 1, wherein the contacts include an L-shaped cross-section.

12. The connection device according to claim 1, wherein the contacts are curved.
